(19) United States
(12) Patent Application Publication
(10) Pub. No.: US 2025/0356092 A1
(43) Pub. Date: Nov. 20, 2025

(54) METHOD AND APPARATUS FOR TESTING CIRCUIT BASED ON TEST COVERAGE OPTIMIZATION

(71) Applicant: Samsung Electronics Co., Ltd., Suwon-si (KR)

(72) Inventors: Seaeun PARK, Suwon-si (KR); Saeeun Kim, Suwon-si (KR); Thai Hoang Nguyen, Seoul (KR); Joon-Sung Yang, Seoul (KR)

(73) Assignee: Samsung Electronics Co., Ltd., Suwon-si (KR)

(21) Appl. No.: 18/929,132

(22) Filed: Oct. 28, 2024

(30) Foreign Application Priority Data
May 14, 2024 (KR) 10-2024-0063373

(51) Int. Cl. G06F 30/333; G06F 30/327

(52) U.S. Cl. CPC G06F 30/333; G06F 30/327

(57) ABSTRACT

A method and apparatus for testing a circuit based on test coverage optimization are provided. The method includes converting design data representing circuit components and circuit nodes of a circuit to be tested into graph data, generating test coverage of the design data and influence data representing influence of the circuit nodes for the test coverage based on the graph data input in a graph neural network (GNN) model, and selecting test points for test point insertion (TPI) from the circuit nodes, based on the influence data.

### CROSS-REFERENCE TO RELATED APPLICATION

This application is based on and claims priority from Korean Patent Application No. 10-2024-0063373, filed on May 14, 2024, in the Korean Intellectual Property Office, the disclosure of which is incorporated herein by reference in its entirety.

### BACKGROUND

### 1. Field

The disclosure relates to methods and apparatuses for testing a circuit, and in particular, to methods and apparatuses for testing a circuit test based on test coverage optimization.

### 2. Description of the Related Art

In a circuit testing technology, design for testability (DFT) refers to a design for ease of testing. For example, DFT may refer to a design technique for testing an electronic circuit or a system more easily. The DFT technique may include, but is not limited to, a scan chain, a built-in self-test (BIST), or a boundary scan. DFT of a circuit or a system may help effectively discover and diagnose defects during a manufacturing process. Moreover, DFT may play an important role in increasing product reliability, reducing manufacturing costs, and reducing the time to market a product. Accordingly, it may be beneficial to consider the DFT strategy from the initial stage of circuit design.

### SUMMARY

One or more embodiments may address at least the above problems and/or disadvantages and other disadvantages not described above. Also, the embodiments are not required to overcome the disadvantages described above, and an embodiment may not overcome any of the problems described above.

According to an aspect of the disclosure, there is provided a method performed by an electronic device, the method including: converting design data representing a plurality of circuit components and a plurality of circuit nodes of a circuit to be tested into graph data; generating test coverage data and influence data representing influence of the plurality of circuit nodes based on the graph data input to a graph neural network (GNN) model; and selecting one or more test points for test point insertion (TPI) from the plurality of circuit nodes, based on the influence data.

According to an aspect of the disclosure, there is provided a non-transitory computer-readable storage medium storing instructions that, when executed by a processor, cause the processor to perform a method including: converting design data representing a plurality of circuit components and a plurality of circuit nodes of a circuit to be tested into graph data; generating test coverage data and influence data representing influence of the plurality of circuit nodes based on the graph data input to a graph neural network (GNN) model; and selecting one or more test points for test point insertion (TPI) from the plurality of circuit nodes, based on the influence data.

According to an aspect of the disclosure, there is provided an electronic device including: a memory configured to store instructions; and one or more processors configured to execute the instructions to cause the electronic device to: convert design data representing a plurality of circuit components and a plurality of circuit nodes of a circuit to be tested into graph data; generate test coverage data and influence data representing influence of the plurality of circuit nodes based on the graph data input to a graph neural network (GNN) model; and select one or more test points for test point insertion (TPI) from the plurality of circuit nodes, based on the influence data.

### BRIEF DESCRIPTION OF DRAWINGS

The above and/or other aspects will be more apparent by describing certain embodiments, taken in conjunction with the accompanying drawings, in which:

FIG. 1 is a diagram illustrating an example of a circuit to be tested according to an embodiment;

FIG. 2A is a diagram illustrating an example of test point insertion (TPI) according to related art;

FIG. 2B is a diagram illustrating an example of test point insertion (TPI) according to an embodiment;

FIG. 3 is a diagram illustrating an example of a process of data format conversion and test coverage prediction according to an embodiment;

FIGS. 4A to 4C are diagrams illustrating an example of data format conversion according to an embodiment;

FIG. 5 is a diagram illustrating an additional example of data format conversion according to an embodiment;

FIG. 6 is a diagram illustrating an example of a structure of a graph neural network (GNN) model according to an embodiment;

FIG. 7 is a diagram illustrating an example of influence data according to an embodiment;

FIG. 8 is a diagram illustrating an example of a training process of a GNN model according to an embodiment;

FIG. 9 is a flowchart illustrating an example of a circuit test method based on test coverage optimization according to an embodiment; and

FIG. 10 is a diagram illustrating an example of a configuration of an electronic device according to an embodiment.

### DETAILED DESCRIPTION

The following detailed structural or functional description is provided as an example only and various alterations and modifications may be made to the embodiments. Accordingly, the embodiments are not construed as limited to the disclosure and should be understood to include all changes, equivalents, and replacements within the idea and the technical scope of the disclosure.

Although terms, such as first, second, and the like are used to describe various components, the components are not limited to the terms. These terms should be used only to distinguish one component from another component. For example, a first component may be referred to as a second component, or similarly, the second component may be referred to as the first component.

It should be noted that if it is described that one component is “connected”, “coupled”, or “joined” to another component, a third component may be “connected”, “coupled”, and “joined” between the first and second components, although the first component may be directly connected, coupled, or joined to the second component.

The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

As used herein, “at least one of A and B”, “at least one of A, B, or C,” and the like, each of which may include any one of the items listed together in the corresponding one of the phrases, or all possible combinations thereof.

Unless otherwise defined, all terms, including technical and scientific terms, used herein have the same meaning as commonly understood by one of ordinary skill in the art to which this disclosure pertains. Terms, such as those defined in commonly used dictionaries, should be construed to have meanings matching with contextual meanings in the relevant art, and are not to be construed to have an ideal or excessively formal meaning unless otherwise defined herein.

Hereinafter, embodiments will be described in detail with reference to the accompanying drawings. When describing the embodiments with reference to the accompanying drawings, like reference numerals refer to like elements and a repeated description related thereto will be omitted.

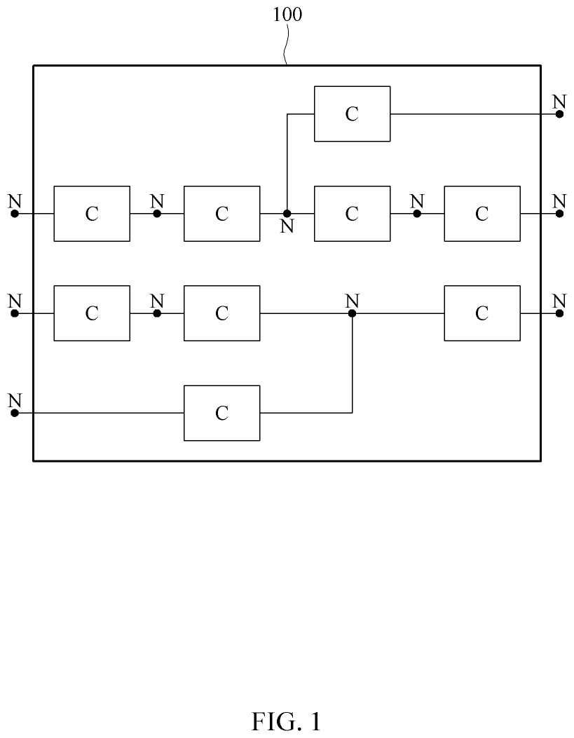

FIG. 1 is a diagram illustrating an example of a circuit to be tested according to an embodiment. Referring to FIG. 1, a circuit 100 to be tested may include circuit components C and circuit nodes N. The circuit 100 in FIG. 1 illustrates for ease of description, but the disclosure is not limited thereto. As such, according to another embodiment, a number of circuit components and a number of circuit nodes are not limited to the illustration in FIG. 1. Also, the disclosure is not limited to the arrangement of the circuit components and the circuit nodes. The circuit nodes N may be different from graph nodes to be described below.

According to an embodiment, design data of the circuit 100 may represent the circuit components C and the circuit nodes N. The circuit 100 and the design data may have an equivalent relationship. For example, the design data may include, but is not limited to a netlist. For example, the circuit nodes N may be identified by a net name in the netlist. However, the disclosure is not limited thereto, and as such, the circuit components C and the circuit nodes N may be identified in another manner. For example, the design data may include another type of data to represent a relationship between the circuit components C and the circuit nodes N.

According to an embodiment, the circuit components C may include, but is not limited to, one or more components at a register transfer level (RTL), one or more components at a gate level, or a combination of RTL components and gate level components. For example, the circuit components C may include, but is not limited to, a logic gate, such as an AND gate, an OR gate, a NOT gate, a not AND (NAND) gate, a not OR (NOR) gate, an exclusive OR (XOR) gate, and an exclusive NOR (XNOR) gate.

According to an embodiment, defects in the circuit 100 may be checked through a test procedure. In the test procedure, it may be evaluated whether the circuit 100 achieves functional requirements and performance goals through various test patterns. The test result may include test coverage as a result item. However, an uncontrollable input/output (I/O) and/or an unobservable I/O of the circuit 100 may degrade the test coverage. The uncontrollable I/O may refer to an input signal or an output signal that may not be controlled using external test equipment in the test procedure. The unobservable I/O may refer to an input signal or an output signal that may not be observed using external test equipment in the test procedure.

Design for testability (DFT) refers to a design for ease of testing and may refer to a design technique for testing an electronic circuit or a system more easily. For example, a test point insertion (TPI) technique may be used for DFT. According to the TPI technique, one or more test points may be selected from, among a plurality of circuit nodes N, and signals of the one or more test points may be controlled or observed using an additional circuit. The TPI technique may increase test coverage. However, design overhead may increase due to the additional circuit of the TPI technique. High design overhead may reduce production efficiency. According to an embodiment, the test points may be derived based on test coverage optimization that uses a graph neural network (GNN) model.

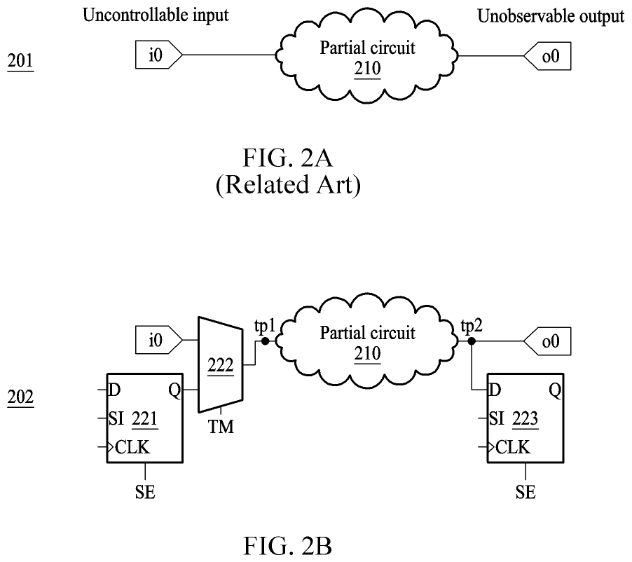

FIG. 2A is a diagram illustrating an example of test point insertion (TPI) according to related art, and FIG. 2B is a diagram illustrating an example of TPI according to an embodiment. Referring to FIG. 2A, in a related art design 201, an input signal i0 of a partial circuit 210 of a circuit (e.g., the circuit 100 of FIG. 1) may be an uncontrollable input signal, and an output signal o0 may be an unobservable output signal.

Referring to 2B, in a design 202 according to an embodiment, a first test point tp1 and a second test point tp2 may be added. For example, the first test point tp1 and the second test point tp2 may be added to the partial circuit 210, signals of the first and second test points tp1 and tp2 may be measured. For example, a first scan flip-flop 221, a scan flip-flop and 223, and a multiplexer 222 may be used to measure the signals of the first and second test points tp1 and tp2. For example, the first scan flip-flop 221, the scan flip-flop and 223, and the multiplexer 222 may correspond to additional circuits of TPI. In the design 202, the input signal i0 may be a controllable input signal and the output signal o0 may be an observable output signal.

The first and second scan flip-flops 221 and 223 may receive a data signal D, a scan input signal SI, a clock signal CLK, and a scan enable signal SE and may output an output signal Q. According to an embodiment, the first scan flip-flop 221 may receive a data signal D, a scan input signal SI, a clock signal CLK, and a scan enable signal SE and may output an output signal Q to the multiplexer 222. The multiplexer 222 may output the input signal i0 or the output signal Q of the first scan flip-flop 221 based on a test mode control signal TM. For example, the multiplexer 222 may output the input signal i0 or the output signal Q of the first scan flip-flop 221 to a first test point tp2. According to an embodiment, the second scan flip-flop 223 may receive a data signal D, a scan input signal SI, a clock signal CLK, and a scan enable signal SE and may output an output signal Q. For example, the data signal D may be an output at second test point tp2. According to an embodiment, an output signal of the second scan flip-flop 223 may represent a scan result. The first and second scan flip-flops 221 and 223 may output the data signal D or the scan input signal SI based on the scan enable signal SE.

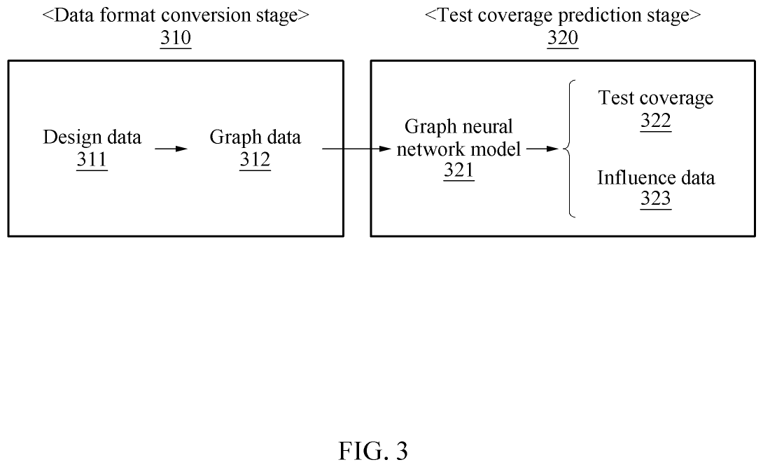

FIG. 3 is a diagram illustrating an example of a process of data format conversion and test coverage prediction according to an embodiment. Referring to FIG. 3, in a data format conversion stage 310, design data 311 may be converted into graph data 312. For example, the design data 311 may be converted into the graph data 312 having a format used in a GNN model 321. However, the disclosure is not limited thereto, and as such, the design data 311 may be converted be converted into a different format. The design data 311 may represent circuit components and circuit nodes of a circuit to be tested.

For example, the graph data 312 may include, but is not limited thereto, a graph node matrix and an edge matrix. The graph node matrix may represent features of the circuit components, and the edge matrix may represent the circuit nodes. For example, the features of the circuit components may include, but are not limited to, a component type, a number of pieces of fan-in, a number of pieces of fan-out, a logic depth, mask information, or a combination thereof. At the gate level, the component type may refer to a gate type. The number of pieces of fan-in may refer to a number of inputs of each circuit component. The number of pieces of fan-out may refer to a number of outputs of each circuit component. The logic depth may refer to a number of circuit components or circuit nodes that exist between an input node and an output node of the circuit. According to an embodiment, in a case in which the logic depth is calculated, a feedback loop in the circuit may be temporarily removed. The mask information may indicate whether each circuit component is constrained or unconstrained.

According to an embodiment, in a test coverage prediction stage 320, test coverage 322 of the design data 311 and influence data 323 representing the influence of each of the circuit nodes for the test coverage 322 may be generated based on the graph data 312. For example, the test coverage 322 and the influence data 323 may be generated by executing the GNN model 321, using the graph data 312.

The design data 311 may include test point candidates. For example, the test point candidates may include one or more circuit nodes. For example, all circuit nodes of the design data 311 may be the test point candidates. However, the disclosure is not limited thereto, and as such, according to an embodiment, one or more circuit nodes of the design data 311 may be the test point candidates. The test coverage 322 may be predicted using the test point candidates of the design data 311.

The GNN model 321 may generate a saliency map corresponding to the prediction of the test coverage 322. The saliency map may represent the influence of each of the circuit nodes of the graph data 312 for the formation of the test coverage 322. The saliency map may be generated in various ways. For example, the saliency map may be generated using a gradient-based method and/or a perturbation-based method. However, the disclosure is not limited thereto, and as such, according to another embodiment, another type of method may be used to generate the saliency map. For example, the saliency map may be generated using the mask information among features of graph nodes. The influence data 323 may be generated from the saliency map.

According to an embodiment, test points for TPI may be selected from the circuit nodes, based on the influence data 323. For example, the test points may be selected in order of influence from the circuit nodes. For example, a first test point, among the test points, having a first level of influence from a first circuit node may be selected before a second test point, among the test points, having a second level of influence from the first circuit node. Here, the first level of influence may be lower than the first level of influence. For example, the test points may be assigned a priority for selection based on a level of influence from the circuit nodes. For example, the test points may be selected in order of priority. For example, the order may be higher priority to a lower priority. However, the disclosure is not limited thereto, and as such, the test points may be selected based on a different criteria. Each circuit node may be a test point candidate. The influence data 323 may represent the influence of each circuit node. The circuit nodes may be sorted according to the influence of each circuit node, and circuit nodes of the upper group may be selected as the test points for TPI.

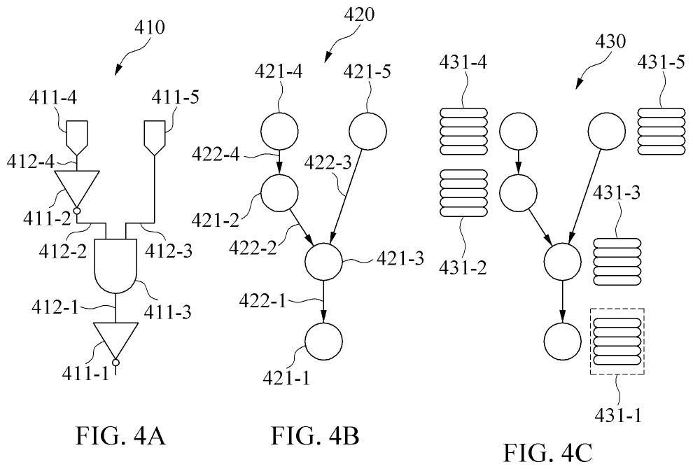

FIGS. 4A-4C are diagrams illustrating an example of data format conversion according to an embodiment. FIG. 4A shows a first visual representation 410 representing circuit components 411-1 to 411-5 and circuit nodes 412-1 to 412-4. FIG. 4B shows a second visual representation 420 representing graph nodes 421-1 to 421-5 corresponding to the circuit components 411-1 to 411-5 and graph edges such as a graph edge 422-1 to 422-4 corresponding to the circuit nodes 412-1 to 412-4. FIG. 4C shows a third visual representation 430 in which component features such as component features 431-1 to 431-5 are added to the second visual representation 420. The first visual representation 410 may represent design data, and the third visual representation 430 may represent graph data.

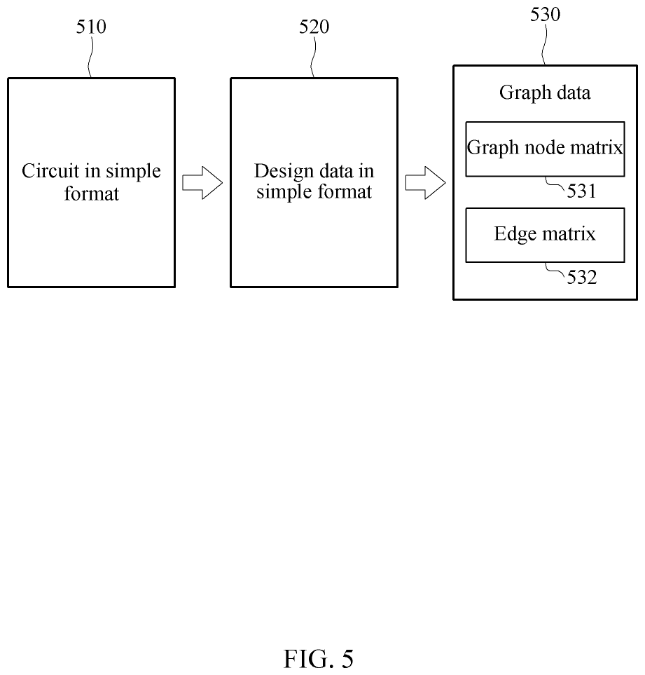

FIG. 5 is a diagram illustrating an additional example of data format conversion according to an embodiment. Referring to FIG. 5, design data in a simple format 520 corresponding to a circuit in a simple format 510 may be used. Original circuit components of design data in an original format may be converted into replacement components of the design data in the simple format 520. For example, the replacement components may have less diversity than the original circuit components. For example, in the design data in the simple format 520, the replacement components may be limited to specific types of components. For example, the types of replacement components may be predetermined. For example, the types of replacement components may be limited to an AND gate, an inverter, and a latch. However, the disclosure is not limited thereto, and as such, the specific type of components may include another type of component. There may be no limitations on the types of original components. According to an embodiment, the design data in the simple format 520 may be used instead of the design data in the original format. For example, the original circuit components may be converted into the replacement components, and graph data 530 may be generated based on the replacement components. The computational complexity may decrease when the design data in the simple format 520 is used.

The graph data 530 may include a graph node matrix 531 and an edge matrix 532. The graph node matrix 531 may represent features of circuit components. For example, the features may include a component type, the number of pieces of fan-in, the number of pieces of fan-out, a logic depth, mask information, or a combination thereof.

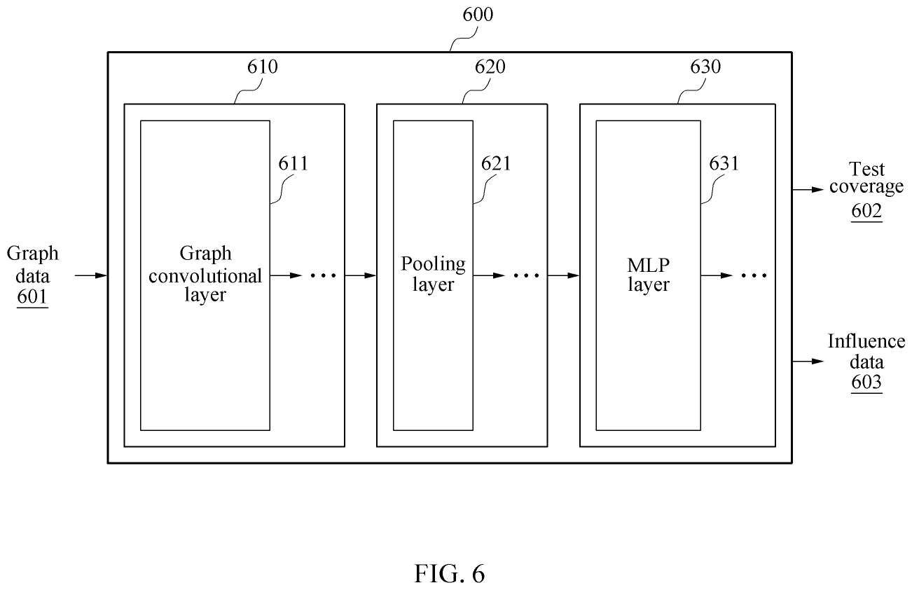

FIG. 6 is a diagram illustrating an example of a structure of a GNN model according to an embodiment. Referring to FIG. 6, a GNN model 600 may include a first layer group 610 including one or more graph convolutional layers 611, a second layer group 620 including one or more pooling layers 621, and a third layer group 630 including one or more multilayer perceptron (MLP) layers 631. The structure of the GNN model 600 shown in FIG. 6 is an example, and the GNN model 600 may have a different structure from that of FIG. 6.

The GNN model 600 may receive graph data 601 as an input, process the graph data 601 using the first to third layer groups 610 to 630, and generate test coverage 602 and influence data 603. The test coverage 602 may be referred be referred to as test coverage data 602. An activation function may be placed between the one or more graph convolutional layers 611 of the first layer group 610. Normalization may be performed on features of all graph nodes in the mini-batch when the one or more graph convolutional layers 611 are executed. A dimension of an output of the first layer group 610 may decrease through the one or more pooling layers 621. For example, the dimension may decrease from the number of nodes times the number of features to 1 times the number of features. The one or more MLP layers 631 may include the activation function.

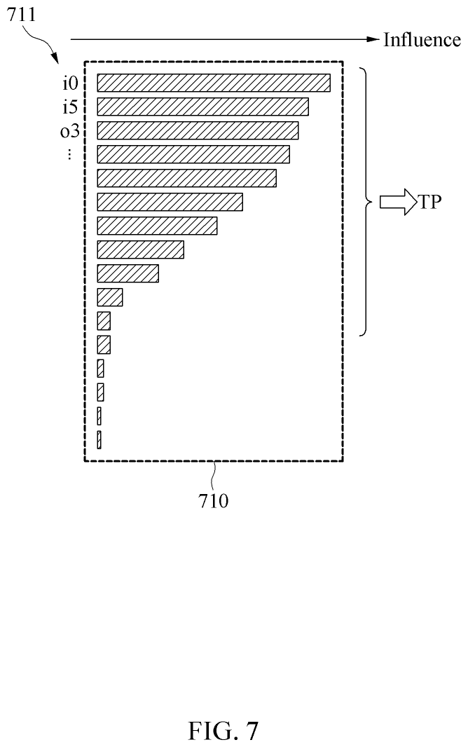

FIG. 7 is a diagram illustrating an example of influence data according to an embodiment. Referring to FIG. 7, influence data 710 may represent the influence of each of circuit nodes 711. The influence data 710 may be expressed by sorting the circuit nodes 711 in order of influence. Test points TPs for TPI may be selected from the circuit nodes 711, based on the influence data 710. For example, one or more of the circuit nodes 711 may be selected as the test points in order of influence from the circuit nodes 711. For example, a circuit node 711 having a higher level of influence may be selected first. For example, based on the illustration in FIG. 7, the circuit node i0 may be selected before the circuit i5. The form of the graph in FIG. 7 is an example and not limited thereto. For example, the influence data 710 may be expressed in a different type of the graph from FIG. 7 or in a form other than the graph.

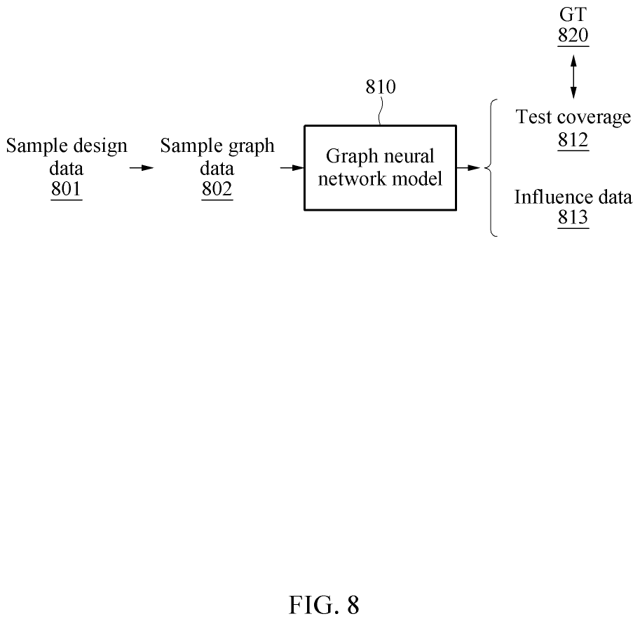

FIG. 8 is a diagram illustrating an example of a training process of a GNN model, according to an embodiment. Referring to FIG. 8, a GNN model 810 may be trained using sample design data 801 and ground truth (GT) 820 as training data. The sample design data 801 may be converted into sample graph data 802. The GNN model 810 may be executed using the sample graph data 802. Accordingly, the GNN model 810 may generate test coverage 812 and influence data 813. The GNN model 810 may be trained based on the difference between the test coverage 812 and the GT 820. Model parameters of the GNN model 810 may be updated through training.

The sample design data 801 may have random test points. The GT 820 may be actual test coverage measured for the random test points of the sample design data 801. That is, the GNN model 810 may be trained based on the sample design data 801 and the actual test coverage of the sample design data 801.

The GNN model 810 may be trained using large-scale training data. Large-scale training data may be obtained using various augmentation techniques. For example, design data of training data may be divided into hierarchical sub-blocks, and large-scale training data may be generated using sub-blocks and test coverage of the sub-blocks.

The GNN model 810 may be trained in advance prior to inference. The GNN model 810 may be used for inference after training is completed. For example, the GNN model 321 of FIG. 3 may correspond to a version in which training of the GNN model 810 of FIG. 8 is completed.

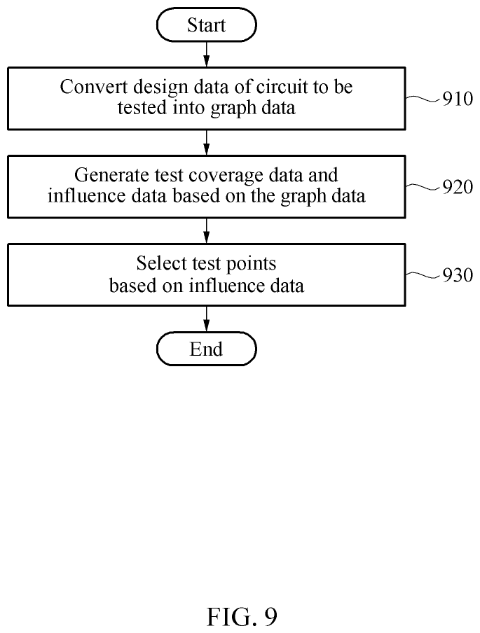

FIG. 9 is a flowchart illustrating an example of a circuit test method based on test coverage optimization according to an embodiment.

Referring to FIG. 9, in operation 910, the method may include converting design data of a circuit to be tested into a graph data. For example, the electronic device may convert design data representing circuit components and/or circuit nodes of a circuit to be tested into graph data. For example, the design data may be converted to graph data having a format used in a GNN model.

According to the embodiment, the design data may include, but is not limited to, a netlist. According to the embodiment, the circuit nodes may be identified by a net name in the netlist.

According to the embodiment, the circuit components may include, but is not limited to, components at an RTL, components at a gate level, or a combination thereof.

According to an embodiment, the graph data may include a graph node matrix representing features of the circuit components and an edge matrix representing the circuit nodes.

According to an embodiment, the features of the circuit components may include, but is not limited to, a component type, a number of pieces of fan-in, a number of pieces of fan-out, a logic depth, mask information, or a combination thereof.

According to an embodiment, the GNN model may generate a saliency map explaining the prediction of the test coverage, and the influence data may be generated from the saliency map.

According to an embodiment, the GNN model may be trained based on sample design data and actual test coverage of the sample design data.

According to an embodiment, the GNN model may include a first layer group including one or more graph convolutional layers, a second layer group including one or more pooling layers, and a third layer including one or more MLP layers.

In operation 920, the method may include generating test coverage data and influence data based on the graph data. For example, the electronic device may generate test coverage data of the design data and influence data representing the influence of each of the circuit nodes for the test coverage by executing the GNN model, using the graph data.

In operation 930, the method may include selecting test points based on the influence data. For example, the electronic device may select test points for test point insertion (TPI) from among the plurality of circuit nodes based on the influence data.

According to an embodiment, in operation 930, the method may include selecting the test points in order of influence from the circuit nodes.

According to an embodiment, in operation 910, the method may include converting the circuit components into replacement components having less diversity than the circuit components and generating the graph data based on the replacement components.

According to an embodiment, the method may further include testing the circuit based on the selecting test points.

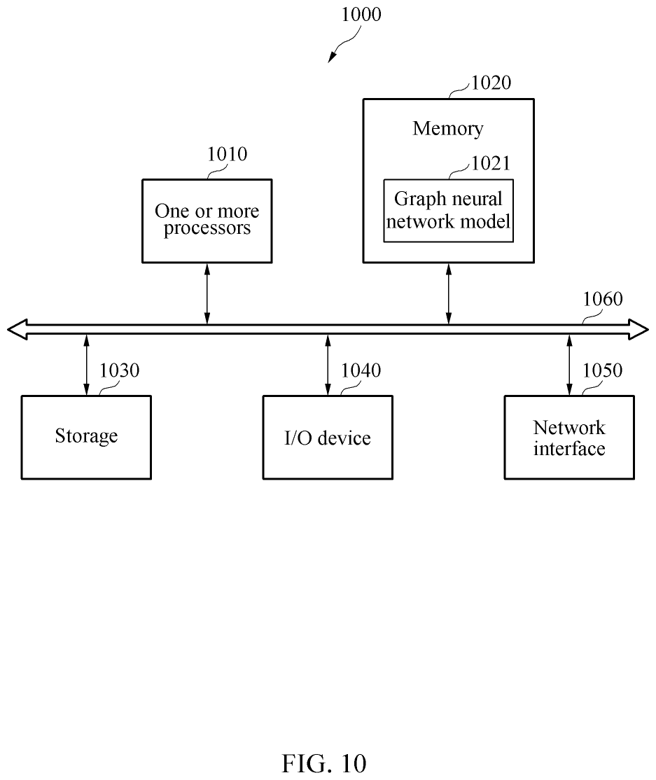

FIG. 10 is a diagram illustrating an example configuration of an electronic device that performs a circuit test method based on test coverage optimization, according to an embodiment. Referring to FIG. 10, an electronic device 1000 may include one or more processors 1010, a memory 1020, a storage 1030, an input/output (I/O) device 1040, and a network interface 1050. According to an embodiment, the one or more processors 1010, the memory 1020, the storage 1030, the I/O device 1040, and the network interface 1050 may communicate with each other via a communication bus 1060. For example, the electronic device 1000 may be implemented as at least part of a computing device such as a desktop or a server.

The one or more processors 1010 may execute instructions stored in the memory 1020 or the storage 1030. The instructions, when executed by the one or more processors 1010, may cause the electronic device 1000 to perform the operations described above with reference to FIGS. 1 to 9. The memory 1020 may include a non-transitory computer-readable storage medium or a non-transitory computer-readable storage device. The memory 1020 may store instructions to be executed by the one or more processors 1010 and may store related information while software and/or applications are executed by the electronic device 1000. According to an embodiment, the memory 1020 may store a GNN model 1021. According to an embodiment, at least a portion of the GNN model 1021 may be stored in the memory 1020, and the operations described above with reference to FIGS. 1 to 9 may be performed by the electronic device 1000.

The storage 1030 may include a non-transitory computer-readable storage medium or a non-transitory computer-readable storage device. The storage 1030 may store a greater amount of information than the memory 1020 and may store the information for a longer period of time. For example, the storage 1030 may include a magnetic hard disk, an optical disk, a flash memory, a floppy disk, or other non-volatile memories known in the art.

The I/O device 1040 may receive an input from a user through an input method including, but not limited to, a keyboard, a mouse, a touch input (e.g., a touch screen), a voice input (e.g., a microphone), an image input (e.g., an image sensor or a camera), or other devices that may detect an input from a user and may transmit the detected input to the electronic device 1000. The I/O device 1040 may provide a user with an output of the electronic device 1000 through a visual channel, an auditory channel, or a tactile channel. The I/O device 1040 may include, for example, a display, a touch screen, a speaker, a vibration generator, or any other device that provides an output to a user. The network interface 1050 may communicate with an external device via a wired or wireless network.

The embodiments described herein may be implemented using a hardware component, a software component, and/or a combination thereof. A processing device (e.g., the one or more processors 1030) may be implemented using one or more general-purpose or special-purpose computers, such as, for example, a processor, a controller and an arithmetic logic unit (ALU), a DSP, a microcomputer, an FPGA, a programmable logic unit (PLU), a microprocessor or any other device capable of responding to and executing instructions in a defined manner. The processing device may run an OS and one or more software applications that run on the OS. The processing device also may access, store, manipulate, process, and create data in response to execution of the software. For purpose of simplicity, the description of a processing device is used as singular; however, one skilled in the art will appreciate that a processing device may include multiple processing elements and/or multiple types of processing elements. For example, the processing device may include a plurality of processors, or a single processor and a single controller. In addition, different processing configurations are possible, such as parallel processors.

The software may include a computer program, a piece of code, an instruction, or some combination thereof, to independently or uniformly instruct or configure the processing device to operate as desired. Software and data may be stored in any type of machine, component, physical or virtual equipment, or computer storage medium or device capable of providing instructions or data to or being interpreted by the processing device. The software also may be distributed over network-coupled computer systems so that the software is stored and executed in a distributed fashion. The software and data may be stored by one or more non-transitory computer-readable recording mediums.

The methods according to the above-described embodiments may be recorded in non-transitory computer-readable media including program instructions to implement various operations of the above-described embodiments. The media may also include, alone or in combination with the program instructions, data files, data structures, and the like. The program instructions recorded on the media may be those specially designed and constructed for the purposes of embodiments, or they may be of the kind well-known and available to those having skill in the computer software arts. Examples of non-transitory computer-readable media include magnetic media such as hard disks, floppy disks, and magnetic tape; optical media such as CD-ROM discs and/or DVDs; magneto-optical media such as optical discs; and hardware devices that are specially configured to store and perform program instructions, such as read-only memory (ROM), random access memory (RAM), flash memory, and the like. Examples of program instructions include both machine code, such as produced by a compiler, and files containing higher-level code that may be executed by the computer using an interpreter.

The above-described hardware devices may be configured to act as one or more software modules in order to perform the operations of the above-described embodiments, or vice versa.

As described above, although the embodiments have been described with reference to the limited drawings, a person skilled in the art may apply various technical modifications and variations based thereon. For example, suitable results may be achieved if the described techniques are performed in a different order, and/or if components in a described system, architecture, device, or circuit are combined in a different manner, or replaced or supplemented by other components or their equivalents.

Accordingly, other implementations are within the scope of the following claims.

What is claimed is:

1. A method performed by an electronic device, the method comprising:
converting design data representing a plurality of circuit components and a plurality of circuit nodes of a circuit to be tested into graph data;
generating test coverage data and influence data representing influence of the plurality of circuit nodes based on the graph data input to a graph neural network (GNN) model; and
selecting one or more test points for test point insertion (TPI) from the plurality of circuit nodes, based on the influence data.

2. The method of claim 1, wherein the graph data comprises a graph node matrix representing features of the plurality of circuit components and an edge matrix representing the plurality of circuit nodes.

3. The method of claim 2, wherein the features of the plurality of circuit components comprise a component type, a number of pieces of fan-in, a number of pieces of fan-out, a logic depth, mask information, or a combination thereof.

4. The method of claim 1, wherein
the GNN model is configured to generate a saliency map corresponding to a prediction of the test coverage data, and
the influence data is generated based on the saliency map.

5. The method of claim 1, wherein the selecting of the one or more test points comprises selecting the one or more test points based on an order of influence from the plurality of circuit nodes.

6. The method of claim 1, wherein the converting of the design data into the graph data comprises:
converting the plurality of circuit components into a plurality of replacement components having less diversity than the plurality of circuit components; and
generating the graph data based on the plurality of replacement components.

7. The method of claim 1, wherein
the design data is a netlist, and
the plurality of circuit nodes are identified by a net name in the netlist.

8. The method of claim 1, wherein the GNN model is trained based on sample design data and actual test coverage of the sample design data.

9. The method of claim 1, wherein the GNN model comprises:
a first layer group comprising one or more graph convolutional layers;
a second layer group comprising one or more pooling layers; and
a third layer group comprising one or more multilayer perceptron (MLP) layers.

10. The method of claim 1, wherein the plurality of circuit components comprise components at a register transfer level (RTL), components at a gate level, or a combination thereof.

11. A non-transitory computer-readable storage medium storing instructions that, when executed by a processor, cause the processor to perform a method comprising:
converting design data representing a plurality of circuit components and a plurality of circuit nodes of a circuit to be tested into graph data;
generating test coverage data and influence data representing influence of the plurality of circuit nodes based on the graph data input to a graph neural network (GNN) model; and
selecting one or more test points for test point insertion (TPI) from the plurality of circuit nodes, based on the influence data.

12. An electronic device comprising:
a memory configured to store instructions; and
one or more processors configured to execute the instructions to cause the electronic device to:
convert design data representing a plurality of circuit components and a plurality of circuit nodes of a circuit to be tested into graph data;
generate test coverage data and influence data representing influence of the plurality of circuit nodes based on the graph data input to a graph neural network (GNN) model; and
select one or more test points for test point insertion (TPI) from the plurality of circuit nodes, based on the influence data.

13. The electronic device of claim 12, wherein the graph data comprises a graph node matrix representing features of the plurality of circuit components and an edge matrix representing the plurality of circuit nodes.

14. The electronic device of claim 13, wherein the features of the plurality of circuit components comprise a component type, a number of pieces of fan-in, a number of pieces of fan-out, a logic depth, mask information, or a combination thereof.

15. The electronic device of claim 12, wherein
the GNN model is configured to generate a saliency map corresponding to a prediction of the test coverage data, and
the influence data is generated based on the saliency map.

16. The electronic device of claim 12, wherein the one or more processors is further configured to select the one or more test points based on an order of influence from the plurality of circuit nodes.

17. The electronic device of claim 12, wherein the one or more processors is further configured to:
convert the plurality of circuit components into a plurality of replacement components having less diversity than the plurality of circuit components, and
generate the graph data based on the plurality of replacement components.

18. The electronic device of claim 12, wherein
the design data is a netlist, and
the plurality of circuit nodes are identified by a net name in the netlist.

19. The electronic device of claim 12, wherein the GNN model is trained based on sample design data and actual test coverage of the sample design data.

20. The electronic device of claim 19, wherein the GNN model comprises:
a first layer group comprising one or more graph convolutional layers;
a second layer group comprising one or more pooling layers; and
a third layer group comprising one or more multilayer perceptron (MLP) layers.
